(19) United States
(12) Patent Application Publication
(10) Pub. No.: US 2025/0385273 A1
(43) Pub. Date: Dec. 18, 2025

(54) ELECTRODE LAYER FOR A HIGH-TEMPERATURE POLYMER ELECTROLYTE MEMBRANE FUEL CELL INCLUDING A POLYMER BINDER

(71) Applicants: HYUNDAI MOTOR COMPANY, Seoul (KR); KIA CORPORATION, Seoul (KR); INDUSTRY-ACADEMIC COOPERATION FOUNDATION GYEONGSANG NATIONAL UNIVERSITY, Jinju-si (KR)

(72) Inventors: Won Jae Choi, Hwaseong-si (KR); Sung Hee Shin, Hwaseong-si (KR); Hyoun Myung Park, Hwaseong-si (KR); Da Hee Kwak, Hwaseong-si (KR); Songi Oh, Hwaseong-si (KR); So Hwa Kim, Hwaseong-si (KR); Jee Youn Hwang, Hwaseong-si (KR); Ah Hyeon Park, Hwaseong-si (KR); Ki Hyun Kim, Yongin-si (KR); Yu Gyeong Jeong, Jinju-si (KR); In Hyeok Hwang, Jinju-si (KR); Hyeon Gyeong Lee, Changwon-si (KR); Chan Hee Choi, Pyeongtaek-si (KR); Soon Sik Hwang, Geoje-si (KR); Yu Eun Kim, Jinju-si (KR)

(73) Assignees: HYUNDAI MOTOR COMPANY, Seoul (KR); KIA CORPORATION, Seoul (KR); INDUSTRY-ACADEMIC COOPERATION FOUNDATION GYEONGSANG NATIONAL UNIVERSITY, Jinju-si (KR)

(21) Appl. No.: 18/968,422

(22) Filed: Dec. 4, 2024

(30) Foreign Application Priority Data
Jun. 17, 2024 (KR) 10-2024-0078265

(51) Int. Cl. H01M 4/86; C08G 61/02; H01M 4/92; H01M 8/10

(52) U.S. Cl. CPC H01M 4/8668; C08G 61/02; H01M 4/926; H01M 8/10; C08G 2261/122; C08G 2261/124; C08G 2261/146; C08G 2261/312; C08G 2261/3142; C08G 2261/42; C08G 2261/72; H01M 2008/1095

(57) ABSTRACT

An electrode layer for a high-temperature polymer electrolyte membrane fuel cell includes a polymer binder having a new structure, in which a phosphate group is introduced into the end of the side chain of a branched polymer binder. The binder itself can exhibit ion conduction properties and can have excellent chemical stability, excellent interfacial bonding properties, and high electrochemical properties.

### CROSS-REFERENCE TO RELATED APPLICATION

This application claims, under 35 U.S.C. § 119 (a), the benefit of priority to Korean Patent Application No. 10-2024-0078265, filed on Jun. 17, 2024, the entire contents of which are incorporated herein by reference.

### BACKGROUND

### Technical Field

The present disclosure relates to an electrode layer for a high-temperature polymer electrolyte membrane fuel cell including a polymer binder having a new structure.

### Background Art

Depending on the operating temperature, polymer electrolyte membrane fuel cells may be classified into low-temperature polymer electrolyte membrane fuel cells that operate in a range of 60° C. to 80° C. and high-temperature polymer electrolyte membrane fuel cells (HT-PEMFC) that operate in a range of 120° C. to 200° C.

Low-temperature polymer electrolyte membrane fuel cells have expensive electrolyte membranes and require a carbon monoxide reducer configured to prevent catalyst poisoning, a water controller configured to precisely maintain water content of the electrolyte membrane, etc.

High-temperature polymer electrolyte membrane fuel cells are driven in a dry environment without water due to operation at high temperatures. Therefore, high-temperature polymer electrolyte membrane fuel cells may solve the problems of electrode flooding and complex humidification systems.

As such, high-temperature polymer electrolyte membrane fuel cells are configured mainly using a phosphoric acid-doped polybenzimidazole (PBI)-based polymer as the electrolyte membrane. A polybenzimidazole-based polymer, having a high glass transition temperature and excellent thermal and physicochemical stability, is widely used as a high-temperature polymer electrolyte membrane.

Also, electrodes of the membrane-electrode assembly in the high-temperature polymer electrolyte membrane fuel cell are composed of a hydrophobic binder such as polytetrafluoroetylene (PTFE), which is a perfluorinated polymer, and a Pt/C catalyst with platinum metal supported on a carbon support. Such electrodes may receive phosphoric acid from the electrolyte membrane by applying physical pressure to the electrolyte membrane doped with an excess of phosphoric acid during manufacture of a membrane-electrode assembly and a stack. Phosphoric acid is present in the pores between PTFE and Pt/C. When protons are transferred through such phosphoric acid, oxidation or reduction reaction occurs on the Pt surface in contact with phosphoric acid.

However, PTFE, which is used as a conventional electrode binder, has low interfacial bonding properties with a commercial ion exchange material. PTFE also has a problem of causing environmental pollution during the disposal process. PTFE further has the disadvantage of making additional reforming reaction difficult due to having high crystallinity.

### SUMMARY OF THE DISCLOSURE

Therefore, the present disclosure has been made keeping in mind the problems encountered in the related art. An object of the present disclosure is to provide an electrode layer for a high-temperature polymer electrolyte membrane fuel cell including a polymer binder having a new structure. The polymer binder itself includes an ion exchange functional group introduced thereto, exhibiting high ion exchange performance, excellent chemical stability, high gas permeability due to lowered crystallinity and increased solubility, and high interfacial bonding properties with commercial ion exchange materials.

The objects of the present disclosure are not limited to the foregoing. The objects of the present disclosure should be more clearly understood through the following description and realized by the electrode layers and high-temperature polymer electrolyte membrane fuel cells described in the claims and through combinations thereof.

An aspect of the present disclosure provides an electrode layer for a high-temperature polymer electrolyte membrane fuel cell. The electrode layer includes a catalyst and a polymer binder having proton conductivity. The polymer binder may include a main chain having at least one of fluorene or biphenyl and a side chain having a branched chain connected to the main chain and a phosphorus (P)-containing functional group located at an end thereof.

In one embodiment, the main chain may include only carbon-carbon bonds.

In one embodiment, the side chain may be linked to carbon at a portion of the main chain other than fluorene and biphenyl.

In one embodiment, the side chain may be linked to carbon at position 9 of fluorene in the main chain.

In one embodiment, the phosphorus (P)-containing functional group may include —PO₃H₂ (where O is oxygen and H is hydrogen).

In one embodiment, the phosphorus (P)-containing functional group may be linked to carbon located at the end of the branched chain.

In one embodiment, the side chain may include fluorobenzene and at least one phosphorus (P)-containing functional group linked to the fluorobenzene.

In one embodiment, the main chain may include an e withdrawing group linked to carbon at a portion other than fluorene and biphenyl.

As such, the e withdrawing group may include —(CF₂)_{z} CF₃ (in which z is a number from 0 to 10) (where C is carbon and F is fluorine).

In one embodiment, the polymer binder may include a copolymer of a repeat unit including fluorene and a repeat unit including biphenyl.

In one embodiment, the catalyst may include a platinum catalyst (Pt/C) supported on a carbon support.

In one embodiment, the polymer binder may be represented by Chemical Formula 1 below.

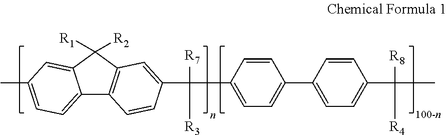

In Chemical Formula 1, each of R₁, R₂, R₃, and R₄ may include hydrogen, a C1-C3 alkyl group, or —(CH₂)ₓ {(PO₃H₂)_{4-y}}ₚ (PO₃H₂) (in which x is a number from 1 to 10, and y is a number from 2 to 4). Further, each of R₁, R₂, R₃, or R₄ may include-(CH₂)ₓ—R₅—{(PO₃H₂)_{4-y}}ₚ (PO₃H₂) (in which x is a number from 1 to 10, and y is a number from 2 to 4). Also, R₅ may include-R₆—(C₆F_{y})ₚ (in which p is 0 or 1) and R₆ may include —CH₂— or —SO₂-(where S is sulfur). Each of R₇ and R₈ may include —(CF₂)_{z}CF₃ (in which z is a number from 0 to 10), and n may satisfy 0<n≤100.

In one embodiment, in Chemical Formula 1, two substituents selected from among R₁, R₂, R₃, and R₄ may include —(CH₂)ₓ—R₅—{(PO₃H₂)_{4-y}}ₚ (PO₃H₂) (in which x is a number from 1 to 10, and y is a number from 1 to 4).

In one embodiment, the polymer binder may be represented by Chemical Formula 2 below.

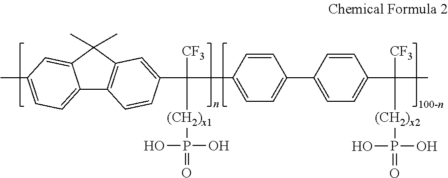

In Chemical Formula 2, each of x1 and x2 may be a number from 1 to 10, and n may satisfy 0<n≤100.

In one embodiment, the polymer binder may be represented by Chemical Formula 3 below.

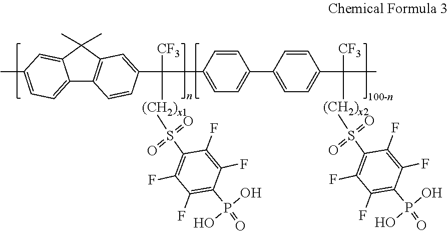

In Chemical Formula 3, each of x1 and x2 may be a number from 1 to 10, and n may satisfy 0<n≤100.

In one embodiment, the polymer binder may be represented by Chemical Formula 4 below.

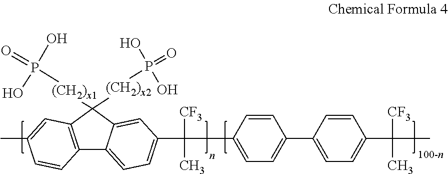

In Chemical Formula 4, each of x1 and x2 may be a number from 1 to 10, and n may satisfy 0<n≤100.

In one embodiment, the polymer binder may be represented by Chemical Formula 5 below.

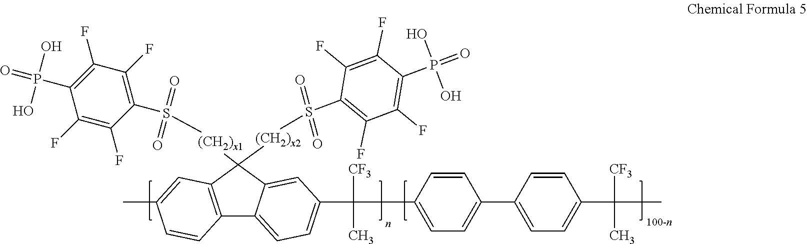

In Chemical Formula 5, each of x1 and x2 may be a number from 1 to 10, and n may satisfy 0<n≤100.

In one embodiment, based on results of Fourier Transform Infrared Spectroscopy (FT-IR) analysis of the polymer binder, a C—H peak at 3000-2840 cm⁻¹, P—OH hydrogen bond peak at 1700-1600 cm⁻¹, and a P—O—H peak at 950-1000 cm⁻¹ may be observed. Also, based on results of FT-IR analysis of the polymer binder, a C—F peak at 1400-1000 cm⁻¹ may be observed.

In one embodiment, based on results of thermogravimetric analysis (TGA) of the polymer binder, a 5% weight loss decomposition temperature (Tas) may be in a range of 260° C. to 310° C.

Another aspect of the present disclosure provides a high-temperature polymer electrolyte membrane fuel cell, including an electrolyte membrane, an anode located on a side of the electrolyte membrane, and a cathode located on a remaining side of the electrolyte membrane, in which the electrode layer described above may be applied to at least one of the anode or the cathode.

In one embodiment, the high-temperature polymer electrolyte membrane fuel cell may operate in a range of 120° C. to 200° C.

### BRIEF DESCRIPTION OF THE DRAWINGS

The above and other features of the present disclosure are described in detail referring to certain embodiments thereof illustrated in the accompanying drawings, which are given hereinbelow by way of illustration only, and thus are not limitative of the present disclosure, and wherein:

FIG. 1 schematically shows a process of synthesizing a polymer binder according to Example 1;

FIG. 2 schematically shows a process of synthesizing a polymer binder according to Example 2;

FIG. 3 shows results of 1H-NMR analysis of the polymer binder according to Example 1 and a starting material used in the synthesis process thereof;

FIG. 4 shows results of ³¹P-NMR analysis of the polymer binder according to Example 1;

FIG. 5 shows results of 1H-NMR analysis of the polymer binder according to Example 2, and a starting material used and intermediate materials formed in the synthesis process thereof;

FIG. 6 shows results of 19F-NMR analysis of the polymer binder according to Example 2 and the intermediate materials formed in the synthesis process thereof;

FIG. 7 shows results of ³¹P-NMR analysis of the polymer binder according to Example 2;

FIG. 8 shows results of Fourier Transform Infrared Spectroscopy (FT-IR) analysis of the polymer binder according to Example 1 and the starting material used in the synthesis process thereof;

FIG. 9 shows results of FT-IR analysis of the polymer binder according to Example 2, and the starting material used and the intermediate materials formed in the synthesis process thereof;

FIG. 10 shows results of thermogravimetric analysis (TGA) of the polymer binders according to Examples 1 and 2; and

FIG. 11 shows results of cell evaluation on membrane-electrode assemblies manufactured using electrode layers to which the polymer binders according to Examples 3 and 4 are applied.

### DETAILED DESCRIPTION

The above and other objects, features and advantages of the present disclosure should be more clearly understood from the following embodiments taken in conjunction with the accompanying drawings. However, the present disclosure is not limited to the embodiments disclosed herein and may be modified into different forms. These embodiments are provided to thoroughly explain the disclosure and to sufficiently transfer the spirit of the present disclosure to those having ordinary skill in the art.

Throughout the drawings, the same reference numerals refer to the same or like elements. For the sake of clarity of the present disclosure, the dimensions of structures maybe depicted as being larger than the actual sizes thereof. It should be understood that, although terms such as “first”, “second”, etc. may be used herein to describe various elements, these elements are not to be limited by these terms. These terms are only used to distinguish one element from another element. For instance, a “first” element discussed below could be termed a “second” element without departing from the scope of the present disclosure. Similarly, the “second” element could also be termed a “first” element. As used herein, the singular forms are intended to include the plural forms as well, unless the context clearly indicates otherwise.

It should be further understood that the terms “comprise”, “include”, “have”, etc., when used in this specification, specify the presence of stated features, integers, steps, operations, elements, components, or combinations thereof. These terms do not preclude the presence or addition of one or more other features, integers, steps, operations, elements, components, or combinations thereof. Also, it should be understood that, when an element such as a layer, film, area, or sheet is referred to as being “on” another element, the element may be directly on the other element, or intervening elements may be present therebetween. Similarly, when an element such as a layer, film, area, or sheet is referred to as being “under” another element, the element may be directly under the other element, or intervening elements may be present therebetween.

Unless otherwise specified, all numbers, values, and/or representations that express the amounts of components, reaction conditions, polymer compositions, and mixtures used herein are to be taken as approximations including various uncertainties affecting measurement that inherently occur in obtaining these values, among others, and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

When a numerical range according to the present specification is explicitly modified by the term “about”, this may be understood to include up to +10% of the stated numerical range.

In the present specification, when a range is described for a variable, it should be understood that the variable includes all values including the end points described within the stated range. For example, the range of “5 to 10” should be understood to include any subranges, such as 6 to 10, 7 to 10, 6 to 9, 7 to 9, and the like, as well as individual values of 5, 6, 7, 8, 9 and 10. The range should also be understood to include any value between valid integers within the stated range, such as 5.5, 6.5, 7.5, 5.5 to 8.5, 6.5 to 9, and the like. Also, for example, the range of “10% to 30%” should be understood to include subranges, such as 10% to 15%, 12% to 18%, 20% to 30%, etc., as well as all integers including values of 10%, 11%, 12%, 13% and the like up to 30%. The range should also be understood to include any value between valid integers within the stated range, such as 10.5%, 15.5%, 25.5%, and the like.

A general polymer electrolyte membrane fuel cell is used in a stack form in which dozens to hundreds of unit cells are stacked and assembled to meet the required output level. Each unit cell includes a bipolar plate, a gas diffusion layer (GDL), an electrode layer (anode, cathode), and a polymer electrolyte membrane (proton exchange membrane), and the polymer electrolyte membrane with two electrodes attached thereto is called a membrane-electrode assembly (MEA). The configuration and performance of MEA may be regarded as the core of a polymer electrolyte membrane fuel cell.

The bipolar plate, gas diffusion layer, electrode layer, and polymer electrolyte membrane included in the polymer electrolyte membrane fuel cell are not limited in shape, thickness, area, etc. unless otherwise defined or explained herein, and may include those commonly used in the art to which the present disclosure pertains.

The electrolyte membrane may include a polymer electrolyte having proton conductivity. The proton conductivity may mean the ability to conduct or exchange protons (H⁺) between the anode and the cathode.

As the electrolyte membrane, a proton conductive polymer commonly used in the field of high-temperature polymer electrolyte membrane fuel cells may be applied. For example, a conventional phosphoric acid-doped polybenzimidazole-based polymer may be used.

Also, as the electrolyte membrane, a proton conductive polymer may include a main chain including at least one of fluorene or biphenyl and a side chain including a branched chain connected to the main chain, a nitrogen (N)-containing functional group located at the end thereof, and a phosphorus (P)-containing functional group connected to the nitrogen-containing functional group by electrostatic attraction. The phosphorus (P)-containing functional group included in the electrolyte membrane and connected to the nitrogen-containing functional group by electrostatic attraction is substantially the same as a phosphorus (P)-containing functional group included in an electrode layer, which is described below, and thus reference may be made thereto.

Furthermore, as the electrolyte membrane, a proton conductive polymer may include a main chain including at least one of fluorene or biphenyl and a side chain including a branched chain connected to the main chain and a sulfur(S)-containing functional group located at the end thereof. The sulfur-containing functional group may include SO₃H or CH₂—SO₃H (where O is oxygen, H is hydrogen, and C is carbon).

The present disclosure relates to an electrode layer that may be applied to the anode or the cathode. The electrode layer for a high-temperature polymer electrolyte membrane fuel cell according to an aspect of the present disclosure may include a catalyst and a polymer binder having proton conductivity. The polymer binder may include a main chain including at least one of fluorene or biphenyl and a side chain including a branched chain connected to the main chain and a phosphorus (P)-containing functional group located at the end thereof. The main chain includes both fluorene and biphenyl.

The polymer binder includes fluorene or biphenyl as a repeat unit and is thus chemically stable. As the polymer binder includes fluorene or biphenyl, the free volume between chains may increase, lowering crystallinity and increasing solubility, resulting in high gas permeability.

In particular, the polymer binder is chemically stable because radically stable fluorene is included as a repeat unit. Furthermore, fluorene may serve to impart torsion to the main chain of the polymer binder, lowering crystallinity. Accordingly, the free volume between chains may increase with an increase in the fluorene content in the main chain of the polymer binder, lowering crystallinity and increasing solubility, resulting in high gas permeability.

Also, the main chain of the polymer binder may include both fluorene and biphenyl, thereby improving the efficiency of controlling molecular weight and physical properties.

Below is a description of the polymer binder using chemical formulas.

The polymer binder according to the present disclosure may be represented by Chemical Formula 1 below.

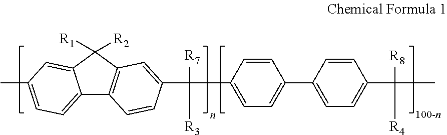

In Chemical Formula 1, each of R₁, R₂, R₃, and R₄ may include hydrogen, a C1-C3 alkyl group, or —(CH₂)ₓ—R₅—{(PO₃H₂)_{4-y}}ₚ (PO₃H₂) (in which x is a number from 1 to 10, and y is a number from 2 to 4).

According to Chemical Formula 1, —(CH₂)ₓ—R₅—{(PO₃H₂)_{4-y}}ₚ (PO₃H₂) may indicate a side chain connected to the main chain, and at least one selected from among R₁, R₂, R₃, or R₄ may include —(CH₂)ₓ—R₅—{(PO₃H₂)_{4-y}}ₚ (PO₃H₂) (in which x is a number from 1 to 10, and y is a number from 2 to 4), and two substituents selected from among R₁, R₂, R₃, and R₄ include —(CH₂)ₓ—R₅—{(PO₃H₂)_{4-y}}ₚ (PO₃H₂) (in which x is a number from 1 to 10, and y is a number from 1 to 4).

Referring to Chemical Formula 1, the polymer binder according to the present disclosure is chemically stable because radically stable fluorene or biphenyl is included as the main chain. In one example, the polymer binder includes fluorene. The free volume between chains may increase with an increase in the fluorene content in the main chain, lowering crystallinity and increasing solubility in an aprotic solvent.

Accordingly, high gas permeability may be exhibited. An increase in the fluorene content in the main chain may mean that the repetition number n of the repeat unit including fluorene increases, and correspondingly, the repetition number 100-n of the repeat unit including biphenyl decreases. Also, n may satisfy 0≤n≤100, in one example may satisfy 0<n≤100, and in another example may satisfy 0<n≤50.

Also, the polymer binder may be synthesized by condensation polymerization of monomers in the presence of an acid catalyst at room temperature within 3 hours, and in one example within 1 hour, which is advantageous for mass production.

In one embodiment, the main chain of the polymer binder according to the present disclosure may be characterized by not including any bonds other than carbon-carbon bonds. Specifically, the main chain may be synthesized through condensation polymerization of a strong acid and thus may be composed of only carbon-carbon bonds. If the main chain includes an aryl ether bond (C_{SP2}—O), a benzylic C—H bond, etc., having low binding energy, it may be decomposed in a high temperature environment. The polymer binder according to the present disclosure does not include the above bonds and therefore has excellent thermal and chemical stability.

In one embodiment, the main chain may include an e withdrawing group linked to carbon at a portion other than fluorene and biphenyl. The e withdrawing group may include —(CF₂)_{z}CF₃ (in which z is a number from 0 to 10) (where F is =fluorine). The e⁻ withdrawing group is —CF₃. Referring to Chemical Formula 1, —(CF₂)_{z}CF₃ (in which z is a number from 0 to 10) may be R₇ and R₈.

The, “group linked to carbon at a portion of the main chain other than fluorene and biphenyl” may be understood as meaning that, when fluorene is defined as a tricyclic aromatic hydrocarbon represented by the chemical formula of (C₆H₄)₂CH₂ and biphenyl is defined as an aromatic hydrocarbon represented by the chemical formula of (C₆H₅)₂, the group is not directly linked to the carbon of fluorene or biphenyl. Also, this is applied equally even when the main chain includes only either fluorene or biphenyl.

The polymer binder according to the present disclosure may exhibit increased reactivity during monomolecular polymerization by including an e withdrawing group linked to carbon at a portion of the main chain other than fluorene and biphenyl.

For reference, the e withdrawing group may be described as —CF₃ in Chemical Formula 1 and Chemical Formulas 2 through 5 as described below, but this is represented as such for convenience and should be understood actually as —(CF₂)_{z}CF₃ (in which z is a number from 0 to 10).

The side chain may be linked to the carbon at a portion of the main chain other than fluorene and biphenyl. Referring to Chemical Formula 1, R₃ and R₄ may include —(CH₂)ₓ—R₅—{(PO₃H₂)_{4-y}}ₚ (PO₃H₂) (in which x is a number from 1 to 10, and y is a number from 1 to 4).

The polymer binder, in which the side chain is linked to the carbon at a portion of the main chain other than fluorene and biphenyl, may be classified depending on whether the phosphorus (P)-containing functional group is directly linked to the carbon of the branched chain or is linked to fluorobenzene in the side chain. The phosphorus (P)-containing functional group is not particularly limited, so long as it is able to impart ion conduction properties to the polymer binder itself and to adjust the acidity of the terminal functional group. An example thereof may include-PO₃H₂.

Referring to Chemical Formula 1, R₅ may include-R₆—(C₆F_{y})ₚ (in which p is 0 or 1), and if p is 0, it may be understood that the phosphorus (P)-containing functional group is directly linked to the carbon of the branched chain. If p is 1, it may be understood that the phosphorus (P)-containing functional group is linked to fluorobenzene in the side chain. Also, R₆ in the R₅ group may include-CH₂— or —SO₂—.

In one embodiment, the phosphorus (P)-containing functional group may be linked to the carbon located at the end of the branched chain in the side chain. This may be represented by Chemical Formula 2 below.

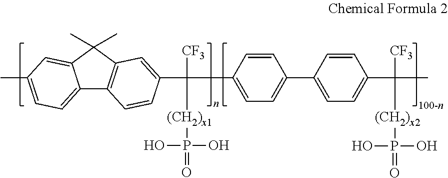

In Chemical Formula 2, x1 and x2 may be respective numbers from 1 to 10, may represent the length of the branched chain in the side chain, and may be the same as or different from each other. Also, n may satisfy 0≤n≤100 and may indicate the ratio of a repeat unit including fluorene and a repeat unit including biphenyl. In one example, n satisfies 0<n≤100, and in another example n satisfies 0<n≤50.

In another embodiment, the side chain may include fluorobenzene and at least one phosphorus (P)-containing functional group linked to the fluorobenzene. This may be represented by Chemical Formula 3 below.

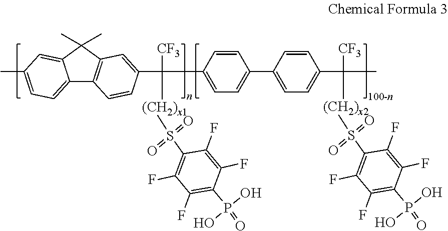

In Chemical Formula 3, x1 and x2 may be respective numbers from 1 to 10, may represent the length of the branched chain in the side chain, and may be the same as or different from each other. Also, n may satisfy 0≤n≤100 and may indicate the ratio of a repeat unit including fluorene and a repeat unit including biphenyl. In one example, n satisfies 0<n≤100, and in another example n satisfies 0<n≤50.

Fluorobenzene is a compound in which the hydrogen group of benzene is substituted with fluorine, in one example, a compound substituted with 2 to 4 fluorine atoms. Therefore, Chemical Formula 3 may be understood to include not only a configuration which includes four fluorine atoms and in which a phosphorus (P)-containing functional group is linked to any one position of fluorobenzene, but also a configuration in which two or three phosphorus (P)-containing functional groups are linked to fluorobenzene.

Also, in Chemical Formula 3, the —SO₂ group is shown as being located between the branched chain and fluorobenzene, but the —SO₂ group is optional and may be removed using a reagent, etc.

The phosphorus (P)-containing functional group may be linked to at least one position selected from among para, ortho, and meta positions of fluorobenzene. In one example, the phosphorus (P)-containing functional group is linked to the para (p) position of fluorobenzene.

The polymer binder, in which the side chain includes fluorobenzene and at least one phosphorus (P)-containing functional group linked to the fluorobenzene as described above, may be configured such that the phosphorus (P)-containing functional group is immediately attached next to fluorophenyl, lowering electron density of phosphorus (P) and increasing acidity. Also, the acidity may be adjusted by controlling the number and location of phosphorus (P)-containing functional groups.

Alternatively, the side chain may be linked to carbon at position 9 of fluorene in the main chain. Specifically, when referring to Chemical Formula 1, the side chain including-(CH₂)ₓ—R₅—{(PO₃H₂)_{4-y}}ₚ (PO₃H₂) (in which x is a number from 1 to 10, and y is a number from 1 to 4) may be R₁ and R₂. The polymer binder, in which the side chain is linked to carbon at position 9 of fluorene in the main chain, may be represented by Chemical Formula 4 or 5 below depending on whether the phosphorus (P)-containing functional group is directly linked to the carbon of the branched chain or is linked to fluorobenzene in the side chain.

The carbon position in fluorene may be represented by the following chemical formula.

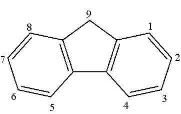 [SMILES: c1ccc2c(c1)Cc1ccccc1-2]

In one embodiment, the phosphorus (P)-containing functional group may be linked to carbon located at the end of the branched chain in the side chain. This may be represented by Chemical Formula 4 below.

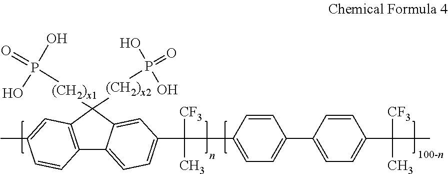

In Chemical Formula 4, x1 and x2 may be respective numbers from 1 to 10, may represent the length of the branched chain in the side chain, and may be the same as or different from each other. Also, n may satisfy 0≤n≤100 and may indicate the ratio of a repeat unit including fluorene and a repeat unit including biphenyl. In one example, n satisfies 0<n≤100, and in another example n satisfies 0<n≤50.

In another embodiment, the side chain may include fluorobenzene and at least one phosphorus (P)-containing functional group linked to the fluorobenzene. This may be represented by Chemical Formula 5 below.

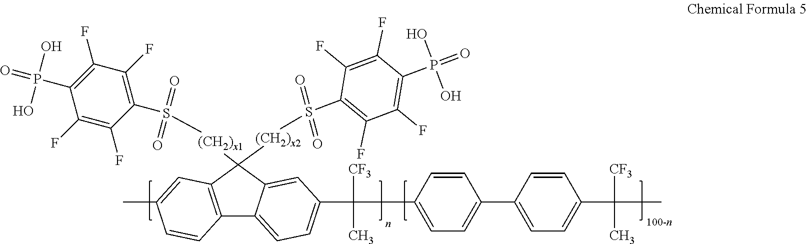

In Chemical Formula 5, x1 and x2 may be respective numbers from 1 to 10, may represent the length of the branched chain in the side chain, and may be the same as or different from each other. Also, n may satisfy 0≤n≤100 and may indicate the ratio of a repeat unit including fluorene and a repeat unit including biphenyl. In one example, n satisfies 0<n≤100, and in another example n satisfies 0<n≤50.

In addition, the branched chain of the side chain, fluorobenzene, —SO₂ group, etc. included in Chemical Formulas 4 and 5 are substantially the same as those described in Chemical Formulas 3 and 4, and thus a description thereof has been omitted.

In one embodiment, the catalyst included in the electrode layer for a high-temperature polymer electrolyte membrane fuel cell may be used without particular limitation, so long as it is a material commonly used in the art to which the present disclosure pertains. Examples of the catalyst may include a noble metal catalyst such as platinum (Pt), etc., a non-noble metal catalyst, an alloy catalyst thereof, and the like. Also, the catalyst is supported on a carbon support and in one example, includes a platinum catalyst (Pt/C) supported on a carbon support.

In one embodiment, based on results of Fourier Transform Infrared Spectroscopy (FT-IR) analysis of the polymer binder, a C—H peak at 3000-2840 cm⁻¹, P—OH hydrogen bond peak 1700-1600 cm 1, and a P—O—H peak at 950-1000 cm⁻¹ may be observed. Also, based on results of FT-IR analysis of the polymer binder, a C—F peak at 1400-1000 cm⁻¹ may be observed.

In one embodiment, based on results of thermogravimetric analysis (TGA) of the polymer binder, a 5% weight loss decomposition temperature (Tas) may be in a range of 260° C. to 310° C. Since the polymer according to the present disclosure has excellent thermal stability at high temperatures, a high-temperature polymer electrolyte membrane fuel cell including the polymer binder may operate at a high temperature in a range of 120° C. to 200° C.

Another aspect of the present disclosure provides a high-temperature polymer electrolyte membrane fuel cell including an electrolyte membrane, an anode located on a side of the electrolyte membrane, and a cathode located on a remaining side of the electrolyte membrane, in which the electrode layer may be applied to at least one of the anode or the cathode.

For example, the high-temperature polymer electrolyte membrane fuel cell according to the present disclosure may include an anode, which is located on a side of the electrolyte membrane and to which the electrode layer is applied to cause oxidation reaction, and a typical cathode. In addition, the high-temperature polymer electrolyte membrane fuel cell according to the present disclosure may include a typical anode located on a side of the electrolyte membrane, and a cathode, which is located on a remaining side of the electrolyte membrane and to which the electrode layer is applied to cause reduction reaction. Furthermore, in the high-temperature polymer electrolyte membrane fuel cell according to the present disclosure, the electrode layer may be applied to both the anode and the cathode.

A better understanding of the present disclosure may be obtained through the following examples and comparative examples. However, these examples are not to be construed as limiting the technical spirit of the present disclosure.

### Example 1

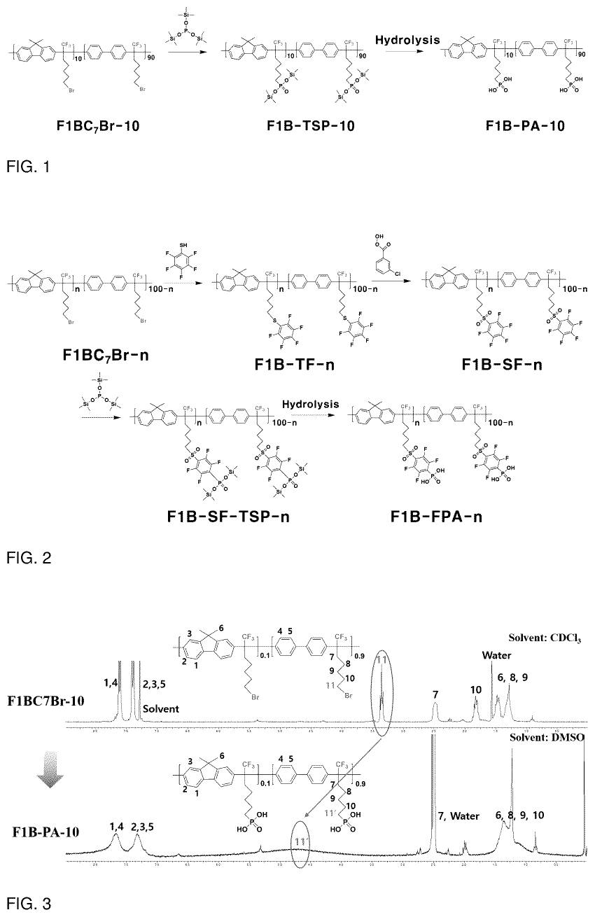

FIG. 1 schematically shows the process of synthesizing a polymer binder according to Example 1.

A starting material F1BC₇Br-10 represented by Chemical Formula 2-1 below was synthesized in the following manner. Specifically, 9,9-dimethylfluorene (1 g, 5.15 mmol), biphenyl (7.14 g, 46.33 mmol), and 7-bromo-1,1,1-trifluoroheptan-2-one (13.99 g, 56.62 mmol) were prepared as monomers. Trifluoromethanesulfonic acid (TFSA) (77.25 g, 514.75 mmol) was prepared as a catalyst. Dichloromethane (DCM) as a reaction solvent was prepared in an amount of 23 parts by weight based on 100 parts by weight of the monomers, and 100 parts by weight of the monomers and the catalyst were added to the reaction solvent to prepare a reactant. The reactant was maintained at about 5° C. for about 30 minutes and then reacted at room temperature (in a range of 20° C. to 25° C.) for about 30 minutes, synthesizing the starting material. A polymer solution in which the starting material was dispersed was precipitated in 1,300 ml of methanol, washed several times with methanol, and dried in a vacuum oven at about 40° C.

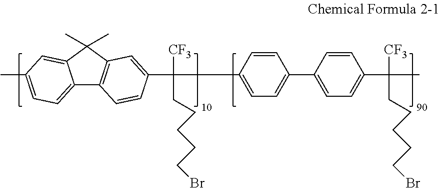

Using the starting material, an intermediate material F1B-TSP-10 represented by Chemical Formula 2-2 below was synthesized in the following manner.

The starting material F1BC₇Br-10 (2 g, 5.16 mmol) and tris(trimethylsilyl) phosphite (4.63 g, 15.49 mmol) were prepared as reaction materials. As a reaction solvent, N,N-Dimethylacetamide (DMAc) was prepared in an amount of 25 parts by weight based on 100 parts by weight of the reaction materials, and 100 parts by weight of the reaction materials were added to the reaction solvent to prepare a reactant. The reactant was reacted at about 150° C. for 5 hours, obtaining a polymer solution including the intermediate material F1B-TSP-10.

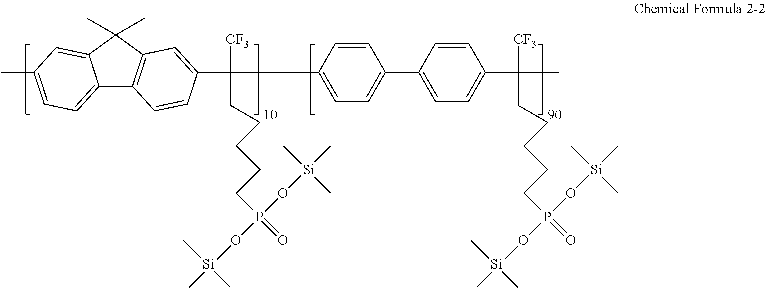

The polymer solution was precipitated and washed in 1,000 ml of distilled water, followed by hydrolysis for 30 minutes, synthesizing a polymer binder (F1B-PA-10) according to Example 1 represented by Chemical Formula 2-3 below. The polymer binder thus obtained was washed several times with distilled water and dried in a vacuum oven at about 40° C., yielding the polymer binder according to Example 1.

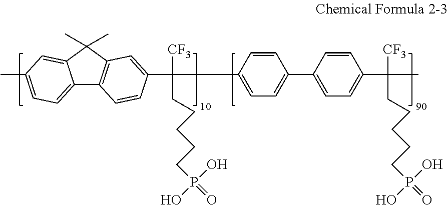

### Example 2

FIG. 2 schematically shows the process of synthesizing a polymer binder according to Example 2.

A starting material F1BC₇Br-10 was synthesized in the same manner as in Example 1. As such, the starting material was represented by Chemical Formula 3-1 to distinguish the same from the starting material in Example 1.

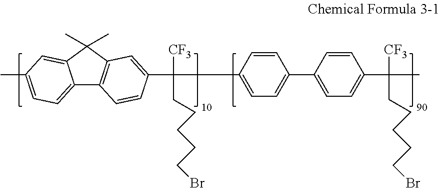

Using the starting material, an intermediate material F1B-TF-10 represented by Chemical Formula 3-2 below was synthesized in the following manner.

The starting material F1BC₇Br-10 (2 g, 5.16 mmol) and pentafluorobenzenethiol (2.07 g, 10.33 mmol) were prepared as reaction materials. Triethylamine (TEA) (1.05 g, 10.33 mmol) was prepared as a catalyst. Dichloromethane (DCM) as a reaction solvent was prepared in an amount of 25 parts by weight based on 100 parts by weight of the reaction materials, and 100 parts by weight of the reaction materials and the catalyst were added to the reaction solvent to prepare a reactant. The reactant was maintained at about 40° C. for about 1 hour, after which the resulting polymer solution was precipitated in 300 ml of methanol, washed several times with methanol, and dried in a vacuum oven at about 40° C.

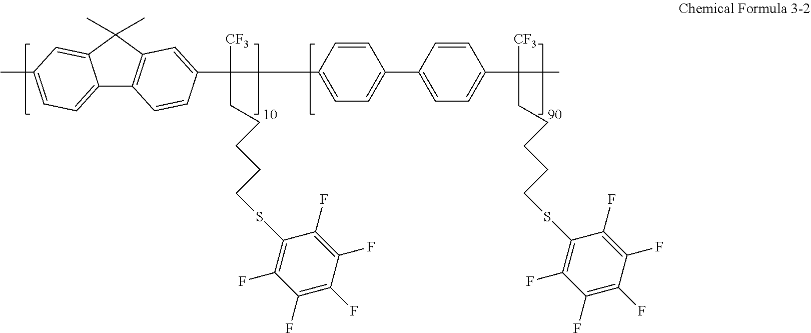

Using the intermediate material F1B-TF-10 represented by Chemical Formula 3-2, an intermediate material F1B—SF-10 represented by Chemical Formula 3-3 below was synthesized in the following manner.

The intermediate material F1B-TF-10 (2 g, 5.16 mmol) and 3-chloroperoxybenzoic acid (3.41 g, 19.76 mmol) were prepared as reaction materials. As a reaction solvent, N,N-Dimethylacetamide (DMAc) was prepared in an amount of parts by weight based on 100 parts by weight of the reaction materials, and 100 parts by weight of the reaction materials were added to the reaction solvent to prepare a reactant. The reactant was maintained at room temperature (in a range of about 20° C. to 25° C.) for 24 hours, obtaining a polymer solution. The polymer solution was precipitated in 300 ml of methanol, washed several times with methanol, and dried in a vacuum oven at about 40° C.

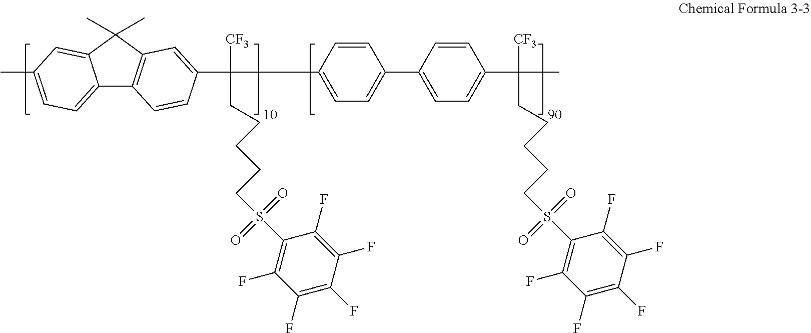

Using the intermediate material F1B—SF-10 represented by Chemical Formula 3-3, an intermediate material F1B-TSP-10 represented by Chemical Formula 3-4 below was synthesized in the following manner.

The intermediate material F1B—SF-10 (1 g, 1.86 mmol) and tris(trimethylsilyl) phosphite (1.66 g, 5.57 mmol) were prepared as reaction materials. Asa reaction solvent, N,N-Dimethylacetamide (DMAc) was prepared in an amount of 30 parts by weight based on 100 parts by weight of the reaction materials, and 100 parts by weight of the reaction materials were added to the reaction solvent to prepare a reactant. The reactant was reacted at about 160° C. for 6 hours, obtaining a polymer solution including the intermediate material F1B-TSP-10.

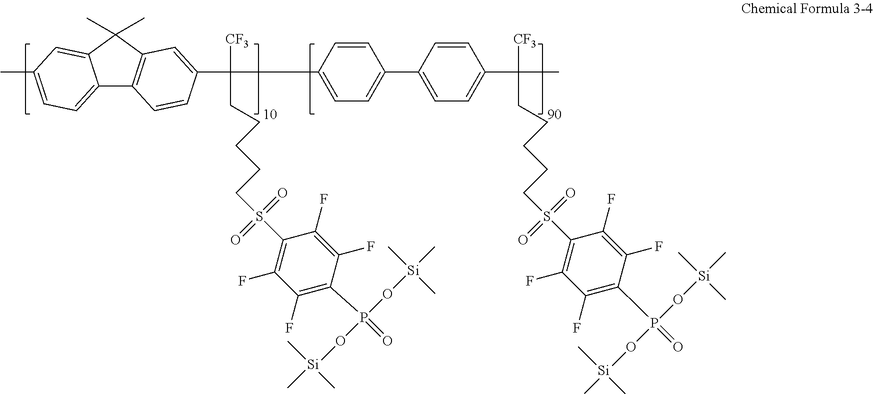

The polymer solution was precipitated and washed in 500 ml of distilled water, followed by hydrolysis for 30 minutes, synthesizing a polymer binder (F1B-FPA-10) according to Example 2 represented by Chemical Formula 3-5 below. The polymer binder thus obtained was washed several times with distilled water and dried in a vacuum oven at about 40° C., yielding the polymer binder according to Example 2.

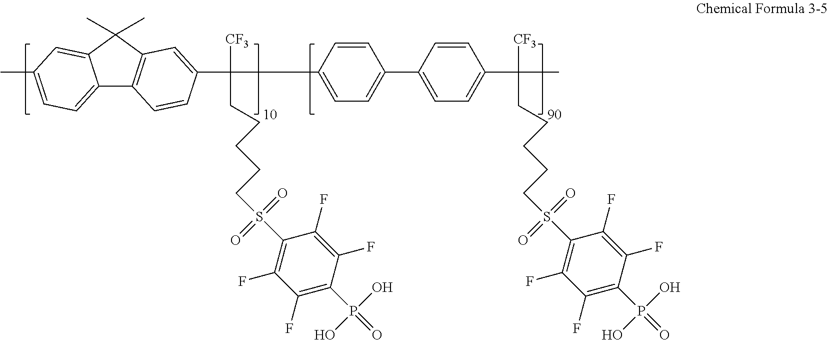

### Example 3

A starting material FLBC₃Br-70 represented by Chemical Formula 4-1 below was synthesized in the following manner. Specifically, 9,9-bis(6-bromohexyl)-9H-fluorene (4.20 g, 8.53 mmol), biphenyl (0.56 g, 3.65 mmol), and 1,1,1-trifluoroacetone (1.50 g, 13.41 mmol) were prepared as monomers. Trifluoromethanesulfonic acid (TFSA) (18.29 g, 13.41 mmol) was prepared as a catalyst. Dichloromethane (DCM) as a reaction solvent was prepared in an amount of 20 parts by weight based on 100 parts by weight of the monomers, and 100 parts by weight of the monomers and the catalyst were added to the reaction solvent to prepare a reactant. The reactant was maintained at about 5° C. for about 1 hour 30 minutes and then reacted at room temperature (in a range of 20° C. to 25° C.) for about 30 minutes, synthesizing the starting material. A polymer solution in which the starting material was dispersed was precipitated in 700 ml of methanol, washed several times with methanol, and dried in a vacuum oven at about 40° C.

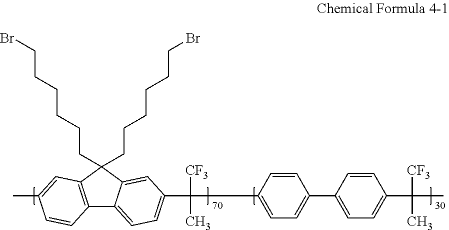

Intermediate materials and a polymer binder (FLB-FPA-70) according to Example 3 represented by Chemical Formula 4-5 below were obtained in the same manner as in Chemical Formulas 3-2 to 3-5 of Example 2, with the exception that the compound represented by Chemical Formula 4-1 was used as the starting material.

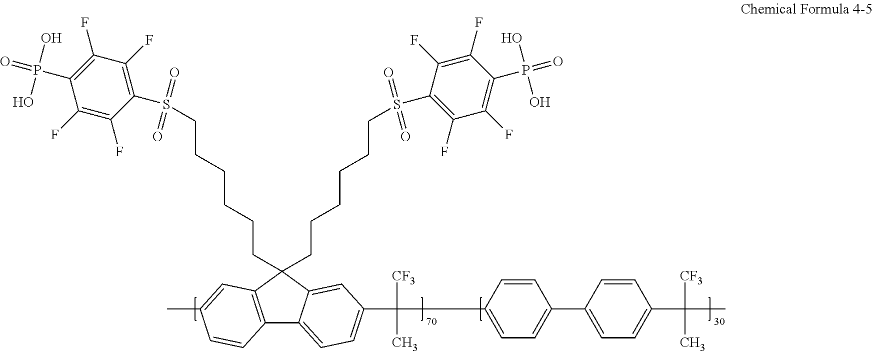

### Example 4

A polymer binder (FLB-FPA-50) was synthesized in the same manner as in Example 3, with the exception that, in the process of synthesizing the polymer binder, the starting material was set such that the ratio of a repeat unit including fluorene and a repeat unit including biphenyl was 50:50.

### Test Example 1

FIG. 3 shows results of 1H-NMR analysis of the polymer binder according to Example 1 and the starting material used in the synthesis process thereof. The progression of reaction was determined through a change in the NMR peak of CH₂ (11) next to the modifiable position (—Br) (where Br is bromine) at the branched end of F1BC₇Br-10 as the starting material. As such, since it is advantageous that all (—Br) s in the starting material are substituted with —PO₃H₂ as a phosphorus (P)-containing functional group, the conversion of the NMR peak of CH₂ (11) adjacent to (—Br) into a peak at position 11′ is 40% or more. If the conversion into the peak at position 11′ is less than 40%, coexistence of —Br and —PO₃H functional groups may cause poor aggregation of the polymer in the process of obtaining the polymer binder, making the precipitation process difficult, which may result in a significant decrease in yield.

Referring to FIG. 3, in the F1B-PA-10 data, synthesis at 100% conversion was confirmed through a complete shift (11′) of the peak at position 11 of F1BC₇Br-10 as the material before reaction.

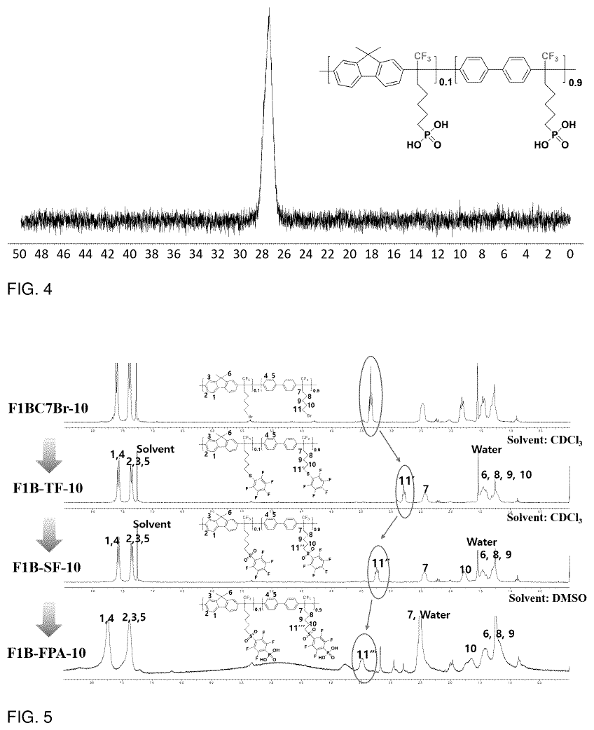

FIG. 4 shows results of ³¹P-NMR analysis of the polymer binder according to Example 1. Referring to FIG. 4, appropriate introduction of —PO₃H₂ as a phosphorus (P)-containing functional group into the polymer binder was confirmed through observation of the P peak of the P—OH functional group.

### Test Example 2

FIG. 5 shows results of 1H-NMR analysis of the polymer binder F1B-FPA-10 according to Example 2, and the starting material F1BC₇Br-10 used and the intermediate materials F1B-TF-10 and F1B—SF-10 formed in the synthesis process thereof. The progression of reaction was determined through a change in the NMR peak of CH₂ (11) next to the modifiable position (—Br) at the branched end of F1BC₇Br-10 as the starting material.

As such, since it is advantageous that all (—Br) s in the starting material are substituted with —PO₃H₂ as a phosphorus (P)-containing functional group, the conversion of the NMR peak of CH₂ (11) adjacent to (—Br) into a peak at position 11″ is 40% or more. If the conversion into the peak at position 11″ is less than 40%, coexistence of —Br and —PO₃H functional groups may cause poor aggregation of the polymer in the process of obtaining the polymer binder, making the precipitation process difficult, which may result in a significant decrease in yield.

Referring to FIG. 5, in the F1B-TF-10, F1B—SF-10, and F1B-FPA-10 data, synthesis at 100% conversion was confirmed through a complete shift (11′, 11″, 11″) of the peak at position 11 of F1BC₇Br-10 as the material before reaction.

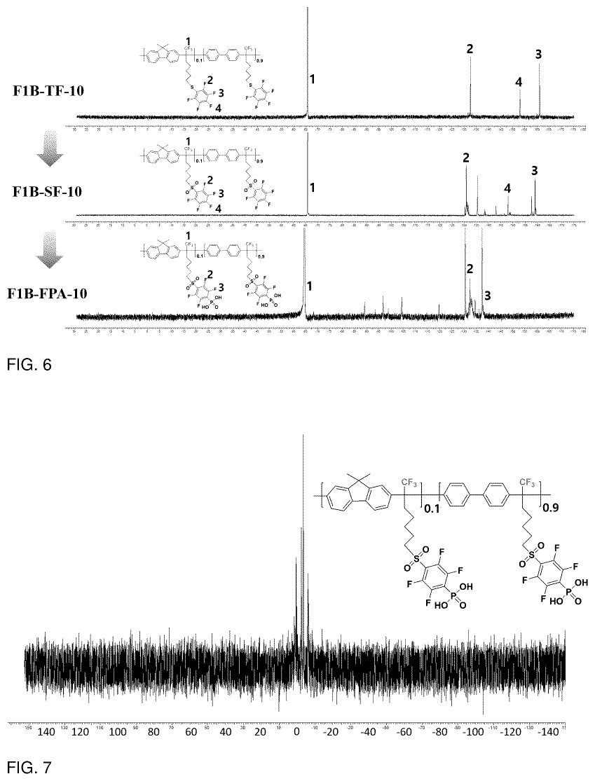

FIG. 6 shows results of 19F-NMR analysis of the polymer binder according to Example 2 and the intermediate materials formed in the synthesis process thereof. The progression of reaction was determined through the generation and change of the NMR peak of (—F) at the branched end of F1BC₇Br-10 as the starting material.

Referring to FIG. 6, in the F1B-TF-10 data, synthesis at 100% conversion was confirmed through the generation of peaks at positions 2, 3, and 4 of pentafluoro. Also, in the F1B—SF-10 data, reaction progression was confirmed through changes of the peaks at positions 2, 3, and 4. Furthermore, in the F1B-FPA-10 data, reaction progression was confirmed through the removal of the peak at position 4 that is modifiable and changes in the peaks at positions 2 and 3.

FIG. 7 shows results of ³¹P-NMR analysis of the polymer binder according to Example 2. Referring to FIG. 7, appropriate introduction of —PO₃H₂ as a phosphorus (P)-containing functional group into the polymer binder was confirmed through observation of the P peak of the P—OH functional group.

### Test Example 3

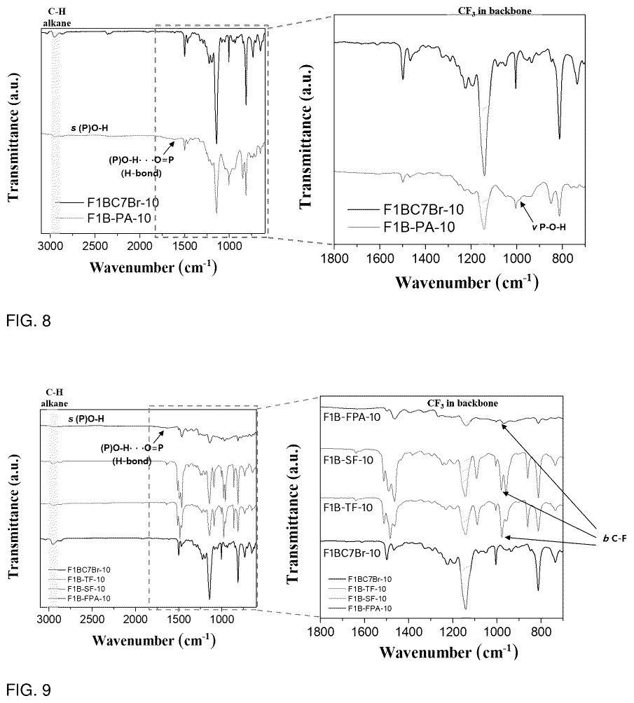

FIG. 8 shows results of FT-IR analysis of the polymer binder F1B-PA-10 according to Example 1 and the starting material F1BC₇Br-10 used in the synthesis process thereof.

Referring to FIG. 8, when comparing the peak of the starting material with the peak of the polymer binder, a C—H peak near 3000-2840 cm⁻¹ was observed, and P—OH hydrogen bond peak near about 1672 cm⁻¹ and a P—O—H peak at about 970 cm⁻¹ were observed. Thereby, changes in the terminal functional group were confirmed. Also, a C—F which is in CF₃ backbone peak near 1400-1000 cm⁻¹ was observed.

### Test Example 4

FIG. 9 shows results of FT-IR analysis of the polymer binder F1B-FPA-10 according to Example 2, and the starting material F1BC₇Br-10 used and the intermediate materials F1B TF-10 and F1B—SF-10 formed in the synthesis process thereof.

Referring to FIG. 9, when comparing the peaks of the starting material and the intermediate materials with the peak of the polymer binder, a C—H peak near 3000-2840 cm⁻¹ was observed, and P—OH hydrogen bond peak near about 1672 cm⁻¹ and a P—O—H peak at about 970 cm⁻¹ were observed. Thereby, changes in the terminal functional group were confirmed. Also, a C—F which is in CF₃ backbone peak near 1400-1000 cm⁻¹ and a C—F which is in fluorobenzene peak at about 982 cm⁻¹ were observed.

### Test Example 5

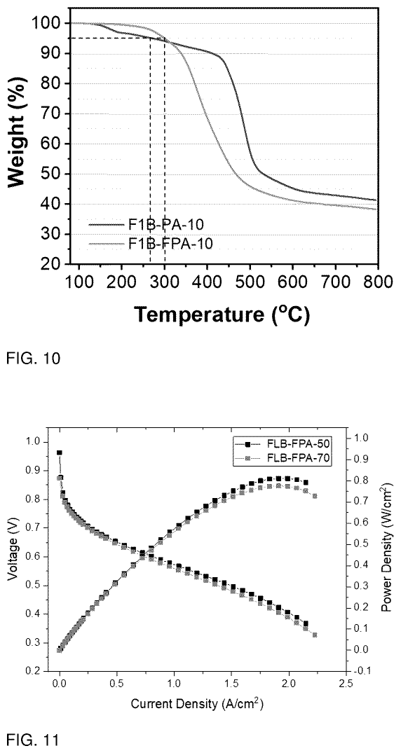

FIG. 10 shows results of thermogravimetric analysis (TGA) of the polymer binders according to Examples 1 and 2.

Specifically, each sample was heated from room temperature to about 120° C. at a rate of about 20° C./min and maintained for about 10 minutes to remove residual water and stabilize the same. Thereafter, the sample was cooled to about 60° C. at a rate of about 20° C./min, followed by heating to about 800° C. at a rate of about 10° C./min under a nitrogen atmosphere and measurement of a change in weight of the sample.

Referring to FIG. 10, the remaining amount was determined to be about 95 wt % at about 269° C. in Example 1 and to be about 95 wt % at about 300° C. in Example 2. Thereby, it can be found that both the polymer binders according to Examples 1 and 2 have vastly superior thermal stability at temperatures equal to or less than 200° C., which is the operating temperature of high-temperature electrolyte membrane fuel cells. Also, “remaining amount” may indicate the ratio of the initial mass of the sample and the mass at the corresponding temperature.

### Test Example 6

FIG. 11 shows results of cell evaluation on membrane-electrode assemblies manufactured using the electrode layers to which the polymer binders according to Examples 3 and 4 are applied.

Specifically, an electrolyte membrane including a phosphoric acid-doped polybenzimidazole-based polymer was purchased and prepared as an electrolyte membrane for a polymer electrolyte membrane fuel cell.

An electrode slurry was prepared by mixing a platinum catalyst Pt/C supported on a carbon support and the polymer binder according to Example 3 and was then applied onto respective sides of the electrolyte membrane for the fuel cell, forming an anode layer on a side of the electrolyte membrane and a cathode layer on a remaining side thereof, thereby manufacturing a membrane-electrode assembly. In addition, a membrane-electrode assembly was manufactured in the same manner as above using the polymer binder according to Example 4 instead of Example 3.

Thereafter, a fuel cell was manufactured by stacking a gas diffusion layer and a bipolar plate on both sides of the membrane-electrode assembly, and cell evaluation was performed by charging and discharging the fuel cell at a current density of 0.2 A/cm² at about 160° C. The results thereof are shown in Table 1 below and FIG. 11.

TABLE 1

| | OCV | Cell V @ | PPD | HFR |
|---|---|---|---|---|
| | (V) | 0.2 A/cm² | (W/cm²) | (mΩ · cm²) |
| FLB-FPA-70 | 0.874 | 0.713 | 0.775 | 80.6 |
| FLB-FPA-50 | 0.963 | 0.717 | 0.810 | 71.6 |

Referring to Table 1 and FIG. 11, the fuel cell including the membrane-electrode assembly to which the polymer binder according to the present disclosure was applied exhibited excellent peak power density (PPD) and high frequency resistance (HFR) even in a high-temperature operating environment of 160° C.

As is apparent from the above description, an electrode layer for a high-temperature polymer electrolyte membrane fuel cell according to the present disclosure has excellent chemical stability because the entire main chain of the polymer electrolyte is composed only of carbon-carbon bonds.

Also, the polymer binder includes radically stable fluorene or biphenyl as a repeat unit and is thus chemically stable. As the polymer binder includes fluorene or biphenyl, the free volume between chains can increase, lowering crystallinity and increasing solubility, which can exhibit high gas permeability.

In addition, the main chain of the polymer binder includes both fluorene and biphenyl, which can improve the efficiency of controlling the molecular weight and physical properties of the polymer binder.

Furthermore, the polymer binder itself has ion exchange properties by including a phosphorus (P)-containing functional group at the end of the side chain, making it possible to manufacture a membrane-electrode assembly with improved performance. In particular, high electrochemical properties can be achieved by adjusting the acidity of the phosphorus (P)-containing functional group.

According to the present disclosure, a monomer that is easy to mass produce is used as a repeat unit of a copolymer, thereby obtaining an electrode layer for a high-temperature polymer electrolyte membrane fuel cell that is easy to produce through condensation polymerization at room temperature in a relatively short time.

The effects of the present disclosure are not limited to the foregoing. It should be understood that the effects of the present disclosure include all effects that can be inferred from the description of the present disclosure.

As the embodiments of the present disclosure have been described above, those having ordinary skill in the art should appreciate that various modifications and alterations are possible through change, deletion, or addition of components without departing from the scope and spirit of the present disclosure as described in the accompanying claims, which are also included within the scope of rights of the present disclosure.

What is claimed is:

1. An electrode layer for a high-temperature polymer electrolyte membrane fuel cell, the electrode layer comprising:
a catalyst; and
a polymer binder having proton conductivity,
wherein the polymer binder includes
a main chain comprising at least one of fluorene or biphenyl, and
a side chain comprising a branched chain connected to the main chain and a phosphorus (P)-containing functional group located at an end thereof.

2. The electrode layer of claim 1, wherein the main chain comprises only carbon-carbon bonds.

3. The electrode layer of claim 1, wherein the side chain is linked to carbon at a portion of the main chain other than fluorene and biphenyl.

4. The electrode layer of claim 1, wherein the side chain is linked to carbon at position 9 of fluorene in the main chain.

5. The electrode layer of claim 1, wherein the phosphorus (P)-containing functional group comprises-PO₃H₂ (where O is oxygen and H is hydrogen).

6. The electrode layer of claim 1, wherein the phosphorus (P)-containing functional group is linked to carbon located at the end of the branched chain.

7. The electrode layer of claim 1, wherein the side chain comprises fluorobenzene and at least one phosphorus (P)-containing functional group linked to the fluorobenzene.

8. The electrode layer of claim 1, wherein the main chain comprises an e withdrawing group linked to carbon at a portion other than fluorene and biphenyl.

9. The electrode layer of claim 8, wherein the e withdrawing group comprises-(CF₂)_{z}CF₃ (in which z is a number from 0 to 10) (wherein C is carbon and F is fluorine).

10. The electrode layer of claim 1, wherein the polymer binder comprises a copolymer of a repeat unit comprising fluorene and a repeat unit comprising biphenyl.

11. The electrode layer of claim 1, wherein the catalyst comprises a platinum catalyst (Pt/C) supported on a carbon support.

12. The electrode layer of claim 1, wherein the polymer binder is represented by Chemical Formula 1 below: 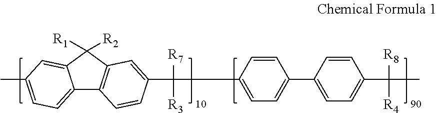
wherein, in Chemical Formula 1
R₁, R₂, R₃, and R₄ each comprise hydrogen, a C₁-C₃ alkyl group, or —(CH₂)ₓ—R₅—{(PO₃H₂)_{4-y}}ₚ(PO₃H₂) (in which x is a number from 1 to 10, and y is a number from 2 to 4) (where H is hydrogen, C is carbon, P is phosphorus, and O is oxygen),
at least one selected from among R₁, R₂, R₃, or R₄ comprises-(CH₂)ₓ—R₅—{(PO₃H₂)_{4-y}}ₚ (PO₃H₂) (in which x is a number from 1 to 10, and y is a number from 2 to 4),
R₅ comprises-R₆—(C₆F_{y})ₚ (in which p is 0 or 1) (where F is fluorine),
R₆ comprises-CH₂— or —SO₂-(where S is sulfur),
R₇ and R₈ each comprise-(CF₂)_{z}CF₃ (in which z is a number from 0 to 10), and
n satisfies 0<n≤100.

13. The electrode layer of claim 12, wherein, in Chemical Formula 1, any two substituents selected from among R₁, R₂, R₃, and R₄ comprise-(CH₂)ₓ—R₅—{(PO₃H₂)_{4-y}}ₚ (PO₃H₂) (in which x is a number from 1 to 10, and y is a number from 1 to 4).

14. The electrode layer of claim 1, wherein the polymer binder is represented by Chemical Formula 2 below: 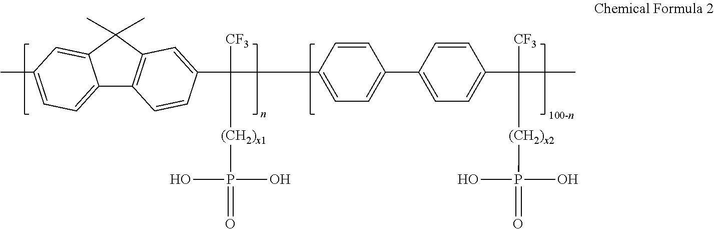
wherein, in Chemical Formula 2, each of x1 and x2 is a number from 1 to 10 (where H is hydrogen, C is carbon, P is phosphorus, F is fluorine, and O is oxygen) and n satisfies 0<n≤100.

15. The electrode layer of claim 1, wherein the polymer binder is represented by Chemical Formula 3 below: 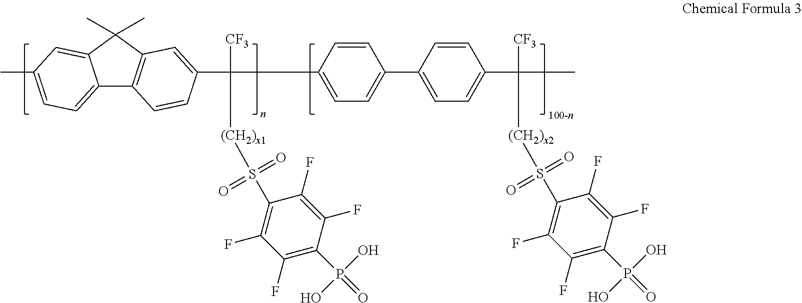
wherein, in Chemical Formula 3, each of x1 and x2 is a number from 1 to 10 (where H is hydrogen, C is carbon, P is phosphorus, F is fluorine, S is sulfur, and O is oxygen) and n satisfies 0<n≤100.

16. The electrode layer of claim 1, wherein the polymer binder is represented by Chemical Formula 4 below: 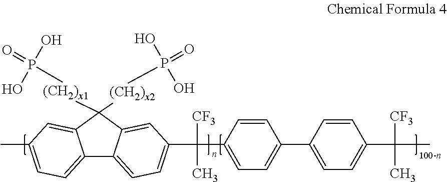
wherein, in Chemical Formula 4, each of x1 and x2 is a number from 1 to 10 (where H is hydrogen, C is carbon, P is phosphorus, F is fluorine, and O is oxygen) and n satisfies 0<n≤100.

17. The electrode layer of claim 1, wherein the polymer binder is represented by Chemical Formula 5 below: 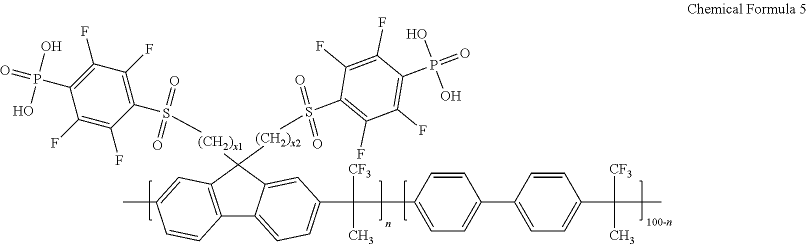
wherein, in Chemical Formula 5, each of x1 and x2 is a number from 1 to 10 (where H is hydrogen, C is carbon, P is phosphorus, F is fluorine, S is sulfur, and O is oxygen); and n satisfies 0<n≤100.

18. The electrode layer of claim 1, wherein, based on results of Fourier Transform Infrared Spectroscopy (FT-IR) analysis of the polymer binder, a C—H peak at 3000-2840 cm⁻¹, P—OH hydrogen bond peak at 1700-1600 cm⁻¹, a P—O—H peak at 950-1000 cm⁻¹, and a C—F peak at 1400-1000 cm 1 are observed (wherein C is carbon, H is hydrogen, F is fluorine, O is oxygen, and P is phosphorus).

19. A high-temperature polymer electrolyte membrane fuel cell, comprising:
an electrolyte membrane;
an anode located on a side of the electrolyte membrane; and
a cathode located on a remaining side of the electrolyte membrane,
wherein the electrode layer of claim 1 is applied to at least one of the anode or the cathode.

20. The high-temperature polymer electrolyte membrane fuel cell of claim 19, wherein the high-temperature polymer electrolyte membrane fuel cell operates in a range of 120° C. to 200° C.
